(19) United States
(12) Patent Application Publication
(10) Pub. No.: US 2025/0297352 A1
(43) Pub. Date: Sep. 25, 2025

(54) OXIDE BUFFER LAYER TO PROMOTE TI02 CRYSTALLINITY AND INCREASE TI02 REFRACTIVE INDEX FOR OPTICAL APPLICATIONS

(71) Applicant: INTERMOLECULAR, INC., SAN JOSE, CA (US)

(72) Inventors: JINGANG SU, SAN JOSE, CA (US); WENXIAN ZHU, SAN JOSE, CA (US); SANG MIN LEE, SANTA CLARA, CA (US)

(21) Appl. No.: 18/869,031

(22) PCT Filed: May 24, 2023
(86) PCT No.: PCT/US2023/023322

§ 371 Date: Nov. 25, 2024

Related U.S. Application Data
(60) Provisional application No. 63/365,362, filed on May 26, 2022.

(51) Int. Cl. C23C 14/00; C23C 14/02; C23C 14/08

(52) U.S. Cl. CPC C23C 14/0036; C23C 14/024; C23C 14/083; C23C 14/086

(57) ABSTRACT

The disclosed and claimed method provides a method for producing high refractive index rutile TiO₂ at moderate process temperatures.

### BACKGROUND

### Field

The disclosed and claimed subject matter relates to a method for producing high refractive index rutile TiO₂ at moderate process temperatures.

### Related Art

TiO₂ is widely used as a high refractive index material in multiple optical coating applications, including anti-reflective coatings, LEDs components, display components, Bragg reflectors, lenses, etc. TiO₂ exhibits one of the highest refractive indexes among binary transition metal oxides, while keeping negligible optical absorption in the visible range. It is also an extremely stable oxide, which makes it attractive from an integration point of view. Notably, higher TiO2 refractive index will improve BDR (distributed Bragg reflector) or ODR (omni-directional reflector) performance, which provides significant value to optical coating.

Unfortunately, deposition by way of known methods, such as sputtering or evaporation processes, yield TiO₂ layers with a refractive index at 460 nm of about only 2.4-2.6. For example, TiO₂ deposited at room temperature exhibits an amorphous structure with relatively low refractive index (2.4 at 460 nm). The anatase phase forms at low process temperatures but it also has a relatively low refractive index comparable to the amorphous phase. The rutile phase is the most attractive one for optical coating applications since it exhibits a very high refractive index (2.7-3 at 460 nm), however it requires a high temperature treatment (600° C.) to be formed. This requirement makes the application of rutile TiO₂ very difficult and impractical from an integration point of view for applications using glass or plastic substrates.

Preferably, the high refractive index TiO₂ is deposited by conventional deposition processes. Such processes include physical vapor deposition (PVD)), chemical vapor deposition (CVD), plasma-enhanced CVD (PECVD), flowable CVD (FCVD), atomic layer deposition (ALD), and spin-on processes.

Transition metal-containing films are used in semiconductor and electronics applications. CVD and ALD have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

Unfortunately, CVD and ALD do not enable deposition of high refractive index materials at lower temperatures. For example, if CVD or ALD is done at 600° C., it may be possible to see a TiO₂ rutile phase. Thus, it is desirable to develop methods by which a rutile phase can be achieved at lower temperatures thereby enabling deposition on sensitive substrates.

The disclosed and claimed PVD process addresses the above difficulties associated with CVD and ALD. PVD is a physical method for deposition of films. A PVD system is comprised by a vacuum chamber able to maintain vacuum during deposition and allow the controlled insertion of different gases, at a typical pressure of 1 mTorr to 10 mTorr. One or several solid targets are inserted in the chamber to serve as sources of the deposited material. In the case of magnetron sputtering deposition, an array of magnets is positioned behind the surface of the targets to help sustaining a plasma in their proximity. The disclosed and claimed subject matter relates to a method for forming a high refractive index layer (e.g., high refractive index rutile TiO₂) using a PVD process at low temperatures.

### SUMMARY

The disclosed and claimed method addresses and largely eliminates these concerns by providing a method for producing high refractive index rutile TiO₂ at moderate process temperatures.

In another embodiment, the disclosed and claimed subject matter includes the generation of high refractive index rutile TiO₂ in PVD deposition processes.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the XRD scans corresponding to the TiO₂ depositions of Example 2.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

The headings employed herein are not intended to be limiting; rather, they are included for organizational purposes only.

### PVD Process

As noted above, the disclosed and claimed subject matter relates to a method producing high refractive index rutile TiO₂ at moderate process temperatures. As deposited, TiO₂ is generally amorphous even at substrate temperature up to 250° C. Consequently, the refractive index of thin film TiO₂ is always lower.

In the disclosed and claimed method, a proper buffer layer is applied to promote TiO₂ crystallinity formation in a subsequent deposition step. When utilized, the method produces TiO₂ with the less favorable rutile crystal structure when a templating transition metal oxide layer buffer layer is used that has the same (or substantially the same) crystal structure and similar lattice constants/spacing to TiO₂. In one embodiment, the templating layer includes one or more of SnO₂, GeO₂, TaO₂ and TeO₂. In one embodiment, the templating layer includes SnO₂. In one embodiment, the templating layer includes GeO₂. In one embodiment, the templating layer includes TaO₂. In one embodiment, the templating layer includes TeO₂. For example, SnO₂ is a good candidate since it has a very close lattice constant to rutile TiO₂ and crystalizes at low temperature Table 1.

TABLE 1
Crystal structure and lattice constants for TiO₂ and SnO₂

| | Crystal structure | Lattice constant a | Lattice constant c |
|---|---|---|---|
| TiO₂ | Rutile | 4.59 Å | 2.96 Å |
| SnO₂ | Rutile | 4.74 Å | 3.2 Å |

The disclosed and claimed PVD process utilizes a mixture of oxygen with one or more inert gases. Exemplary purge gases include, but are not limited to, argon (Ar), nitrogen (N₂), helium (He), neon (Ne), and mixtures thereof. In one embodiment, the inert gas includes argon (Ar). In one embodiment, the inert gas includes nitrogen (N₂). In one embodiment, the inter gas includes helium (He). In one embodiment, the inert gas includes neon (Ne).

The disclosed and claimed subject includes the films deposited by the disclosed and claimed PVD process. The films have thicknesses between about 10 Å and about 50 Å.

### Process Parameters

In one embodiment, the disclosed and claimed PVD process that includes, consists essentially of or consists of the steps of:
(1) depositing a templating layer including one or more of a metal oxide selected from the group of SnO₂, GeO₂, TaO₂, TeO₂ on a substrate surface using a first target by the steps of:
   (a) bringing the substrate to a temperature of about 100° C. to about 400° C.;
   (b) introducing a mixture of oxygen (O) and one or more inert gas;
   (c) performing reactive sputtering by applying voltage to the first target to generate a plasma,
      where the templating layer has a thickness of between about 10 Å and about 125 Å; and
(2) depositing a high refractive index layer of rutile TiO₂ on the templating layer using a second target by the steps of:
   (a) bringing the substrate to a temperature of about 100° C. to about 400° C.;
   (b) introducing a mixture of oxygen (O) and one or more inert gas;
   (c) performing pulsed DC reactive sputtering by applying voltage to the second target to generate a plasma.

In one aspect of this embodiment, the disclosed and claimed PVD process includes step 1 and step 2. In one aspect of this embodiment, the disclosed and claimed PVD process consists essentially of step 1 and step 2. In one aspect of this embodiment, the disclosed and claimed PVD process consists of step 1 and step 2.

In one aspect of this embodiment, the first target includes one or more of a metal oxide material and a metal (i.e., an elemental metal as opposed to a metal-oxide). In one aspect of this embodiment, the first target and the second target are the same. In one aspect of this embodiment, the first target and the second target are different.

In one aspect of this embodiment, the first target includes a metal oxide material. In another aspect of this embodiment, the first target includes a metal oxide material that includes SnO₂. In another aspect of this embodiment, the first target includes a metal oxide material that includes GeO₂. In another aspect of this embodiment, the first target includes a metal oxide material that includes TaO₂. In another aspect of this embodiment, the first target includes a metal oxide material that includes TeO₂.

In one aspect of this embodiment, the first target includes a metal. In another aspect of this embodiment, the first target includes a metal selected from the group of Sn, Ge, Ta and Te.

In another aspect of this embodiment, the first target includes a metal that includes Sn. In another aspect of this embodiment, the first target includes a metal that includes Ge. In another aspect of this embodiment, the first target includes a metal that includes Ta. In another aspect of this embodiment, the first target includes Te. In another aspect of this embodiment, the first target includes a metal that includes two or more of Sn, Ge, Ta and Te. When the first target includes a metal, the reactive sputtering in step 1(c) utilizes a richer oxygen mixture compared to that the oxygen mixture used for a first target that includes a metal oxide material.

In one aspect of this embodiment, the second target includes one or more of a metal oxide material and a metal (i.e., an elemental metal as opposed to a metal-oxide). In one aspect of this embodiment, the second target includes a metal oxide material. In another aspect of this embodiment, the second target includes TiO₂. In one aspect of this embodiment, the second target includes a metal. In another aspect of this embodiment, the second target includes a metal that includes Ti. When the second target includes a metal, the reactive sputtering in step 2(c) utilizes a richer oxygen mixture compared to that the oxygen mixture used for a templating layer that includes a metal oxide material.

the disclosed and claimed PVD process includes step 1 and step 2.

In another aspect of this embodiment, the templating layer includes SnO₂. In another aspect of this embodiment, the templating layer includes GeO₂. In another aspect of this embodiment, the templating layer includes TaO₂. In another aspect of this embodiment, the templating layer includes TeO₂. In another aspect of this embodiment, the templating layer includes two or more of SnO₂, GeO₂, TaO₂ and TeO₂.

In another aspect of this embodiment, in one or both of step 1(a) and step 2(a) the substrate is brought to a temperature of about 125° C. to about 375° C. In another aspect of this embodiment, in one or both of step 1(a) and step 2(a) the substrate is brought to a temperature of about 150° C. to about 375° C. In another aspect of this embodiment, in one or both of step 1(a) and step 2(a) the substrate is brought to a temperature of about 175° C. to about 375° C. In another aspect of this embodiment, in one or both of step 1(a) and step 2(a) the substrate is brought to a temperature of about 200° C. to about 375° C. In another aspect of this embodiment, in one or both of step 1(a) and step 2(a) the substrate is brought to a temperature of about 225° C. to about 375° C. In another aspect of this embodiment, in one or both of step 1(a) and step 2(a) the substrate is brought to a temperature of about 250° C. to about 350° C. In another aspect of this embodiment, in one or both of step 1(a) and step 2(a) the substrate is brought to a temperature of about 275° C. to about 325° C.

In another aspect of this embodiment, in one or both of step 1(a) and step 2(a) the substrate is brought to a temperature of about 100° C. In another aspect of this embodiment, in one or both of step 1(a) and step 2(a) the substrate is brought to a temperature of about 125° C. In another aspect of this embodiment, in one or both of step 1(a) and step 2(a) the substrate is brought to a temperature of about 150° C. In another aspect of this embodiment, in one or both of step 1(a) and step 2(a) the substrate is brought to a temperature of about 175° C. In another aspect of this embodiment, in one or both of step 1(a) and step 2(a) the substrate is brought to a temperature of about 200° C. In another aspect of this embodiment, in one or both of step 1(a) and step 2(a) the substrate is brought to a temperature of about 225° C. In another aspect of this embodiment, in one or both of step 1(a) and step 2(a) the substrate is brought to a temperature of about 250° C. In another aspect of this embodiment, in one or both of step 1(a) and step 2(a) the substrate is brought to a temperature of about 275° C. In another aspect of this embodiment, in one or both of step 1(a) and step 2(a) the substrate is brought to a temperature of about 300° C. In another aspect of this embodiment, in one or both of step 1(a) and step 2(a) the substrate is brought to a temperature of about 325° C. In another aspect of this embodiment, in one or both of step 1(a) and step 2(a) the substrate is brought to a temperature of about 350° C. In another aspect of this embodiment, in one or both of step 1(a) and step 2(a) the substrate is brought to a temperature of about 375° C. In another aspect of this embodiment, in one or both of step 1(a) and step 2(a) the substrate is brought to a temperature of about 400° C.

In one aspect of this embodiment, step 1(a) and step 2(a) are performed at the same temperature. In one aspect of this embodiment, step 1(a) and step 2(a) are performed at substantially the same temperature. In one aspect of this embodiment, step 1(a) and step 2(a) are performed at different temperatures.

In another aspect of this embodiment, in one or both of step 1(b) and step 2(b) the inert gas includes argon (Ar). In another aspect of this embodiment, in one or both of step 1(b) and step 2(b) the inert gas includes nitrogen (N₂). In another aspect of this embodiment, in one or both of step 1(b) and step 2(b) the inter gas includes helium (He). In another aspect of this embodiment, in one or both of step 1(b) and step 2(b) the inert gas includes neon (Ne). In another aspect of this embodiment, the inert gas of step 1(b) is the same as the inert gas of step 2(b). In another aspect of this embodiment, the inert gas of step 1(b) is different than the inert gas of step 2(b).

In one embodiment, one or both of step 1(b) and step 2(b) is carried out at a pressure between about 1 mTorr and about 10 mTorr. In one embodiment, one or both of step 1(b) and step 2 (b) is carried out at a pressure between about 1 mTorr and about 5 mTorr. In one embodiment, one or both of step 1(b) and step 2(b) is carried out at a pressure between about 5 mTorr and about 10 mTorr. In one embodiment, one or both of step 1(b) and step 2(b) is carried out at a pressure between about 3 mTorr and about 7 mTorr. In one embodiment, one or both of step 1(b) and step 2(b) is carried out at a pressure of about 1 mTorr. In one embodiment, one or both of step 1(b) and step 2 (b) is carried out at a pressure of about 2 mTorr. In one embodiment, one or both of step 1(b) and step 2(b) is carried out at a pressure of about 3 mTorr. In one embodiment, one or both of step 1(b) and step 2(b) is carried out at a pressure of about 4 mTorr. In one embodiment, one or both of step 1 (b) and step 2(b) is carried out at a pressure of about 5 mTorr. In one embodiment, one or both of step 1(b) and step 2(b) is carried out at a pressure of about 6 mTorr. In one embodiment, one or both of step 1(b) and step 2(b) is carried out at a pressure of about 7 mTorr. In one embodiment, one or both of step 1(b) and step 2(b) is carried out at a pressure of about 8 mTorr. In one embodiment, one or both of step 1(b) and step 2(b) is carried out at a pressure of about 9 mTorr. In one embodiment, one or both of step 1(b) and step 2(b) is carried out at a pressure of about 10 mTorr.

In one aspect of this embodiment, step 1(b) and step 2(b) are performed at the same pressure. In one aspect of this embodiment, step 1(b) and step 2(b) are performed at substantially the same pressure. In one aspect of this embodiment, step 1(b) and step 2(b) are performed at different pressures.

In another aspect of this embodiment, the templating layer has a thickness of between about 15 Å and about 115 Å. In another aspect of this embodiment, the templating layer has a thickness of between about 25 Å and about 100 Å. In another aspect of this embodiment, the templating layer has a thickness of between about 25 Å and about 75 Å. In another aspect of this embodiment, the templating layer has a thickness of between about 25 Å and about 65 Å. In another aspect of this embodiment, the templating layer has a thickness of between about 25 Å and about 50 Å. In another aspect of this embodiment, the templating layer has a thickness of between about 25 Å and about 35 Å. In another aspect of this embodiment, the templating layer has a thickness of between about 15 Å and about 45 Å. In another aspect of this embodiment, the templating layer has a thickness of between about 20 Å and about 40 Å.

In another aspect of this embodiment, the templating layer has a thickness of about 10 Å. In another aspect of this embodiment, the templating layer has a thickness of about 15 Å.In another aspect of this embodiment, the templating layer has a thickness of about 20 Å. In another aspect of this embodiment, the templating layer has a thickness of about 25 Å. In another aspect of this embodiment, the templating layer has a thickness of about 30 Å. In another aspect of this embodiment, the templating layer has a thickness of about 35 Å. In another aspect of this embodiment, the templating layer has a thickness of about 40 Å. In another aspect of this embodiment, the templating layer has a thickness of about 45 Å. In another aspect of this embodiment, the templating layer has a thickness of about 50 Å. In another aspect of this embodiment, the templating layer has a thickness of about 55 Å. In another aspect of this embodiment, the templating layer has a thickness of about 60 Å. In another aspect of this embodiment, the templating layer has a thickness of about 65 Å. In another aspect of this embodiment, the templating layer has a thickness of about 70 Å. In another aspect of this embodiment, the templating layer has a thickness of about 75 Å. In another aspect of this embodiment, the templating layer has a thickness of about 80 Å. In another aspect of this embodiment, the templating layer has a thickness of about 85 Å. In another aspect of this embodiment, the templating layer has a thickness of about 90 Å. In another aspect of this embodiment, the templating layer has a thickness of about 95 Å. In another aspect of this embodiment, the templating layer has a thickness of about 100 Å. In another aspect of this embodiment, the templating layer has a thickness of about 105 Å. In another aspect of this embodiment, the templating layer has a thickness of about 110 Å. In another aspect of this embodiment, the templating layer has a thickness of about 115 Å. In another aspect of this embodiment, the templating layer has a thickness of about 120 Å. In another aspect of this embodiment, the templating layer has a thickness of about 125 Å.

In another aspect of this embodiment, the step 1(c) performing reactive sputtering voltage is generated by DC. In another aspect of this embodiment, the step 1(c) performing reactive sputtering voltage is generated by RF.

In another aspect of this embodiment, the high refractive index layer of rutile TiO₂ has a refractive index at 460 nm of about 2.70 to about 3.0. In another aspect of this embodiment, the high refractive index layer of rutile TiO₂ has a refractive index at 460 nm of about 2.75 to about 3.0. In another aspect of this embodiment, the high refractive index layer of rutile TiO₂ has a refractive index at 460 nm of about 2.80 to about 3.0. In another aspect of this embodiment, the high refractive index layer of rutile TiO₂ has a refractive index at 460 nm of about 2.85 to about 3.0. In another aspect of this embodiment, the high refractive index layer of rutile TiO₂ has a refractive index at 460 nm of about 2.90 to about 3.0. In another aspect of this embodiment, the high refractive index layer of rutile TiO₂ has a refractive index at 460 nm of about 2.95 to about 3.0. In another aspect of this embodiment, the high refractive index layer of rutile TiO₂ has a refractive index at 460 nm of about 2.70 to about 2.80. In another aspect of this embodiment, the high refractive index layer of rutile TiO₂ has a refractive index at 460 nm of about 2.70 to about 2.75.

In another aspect of this embodiment, the high refractive index layer of rutile TiO₂ has a refractive index at 460 nm of about 2.70 or greater. In another aspect of this embodiment, the high refractive index layer of rutile TiO₂ has a refractive index at 460 nm of about 2.75 or greater. In another aspect of this embodiment, the high refractive index layer of rutile TiO₂ has a refractive index at 460 nm of about 2.80 or greater. In another aspect of this embodiment, the high refractive index layer of rutile TiO₂ has a refractive index at 460 nm of about 2.85 or greater. In another aspect of this embodiment, the high refractive index layer of rutile TiO₂ has a refractive index at 460 nm of about 2.90 or greater. In another aspect of this embodiment, the high refractive index layer of rutile TiO₂ has a refractive index at 460 nm of about 2.95 or greater. In another aspect of this embodiment, the high refractive index layer of rutile TiO₂ has a refractive index at 460 nm of about 3.0 or greater.

In another aspect of this embodiment, the high refractive index layer of rutile TiO₂ has a refractive index at 460 nm of about 2.70. In another aspect of this embodiment, the high refractive index layer of rutile TiO₂ has a refractive index at 460 nm of about 2.75. In another aspect of this embodiment, the high refractive index layer of rutile TiO₂ has a refractive index at 460 nm of about 2.80. In another aspect of this embodiment, the high refractive index layer of rutile TiO₂ has a refractive index at 460 nm of about 2.85. In another aspect of this embodiment, the high refractive index layer of rutile TiO₂ has a refractive index at 460 nm of about 2.90. In another aspect of this embodiment, the high refractive index layer of rutile TiO₂ has a refractive index at 460 nm of about 2.95. In another aspect of this embodiment, the high refractive index layer of rutile TiO₂ has a refractive index at 460 nm of about 3.0.

Suitable substrates on which the disclosed and claimed process can be used are not particularly limited and vary depending on the final use intended. For example, the substrate may be chosen from transition metal oxides, rare earth oxide-based materials, ternary oxide-based materials, etc. or from nitride-based films. Other substrates may include solid substrates such as metal substrates (e.g., Au, Pd, Rh, Ru, W, Al, Ni, Ti, Co, Pt and metal silicides (such as TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); plastics and flexible substrates (e.g., polymers); and combinations thereof. Preferred substrates include glass and silicon oxide-based substrates. In one embodiment, the substrate includes glass. In another embodiment, the substrate includes a silicon oxide-based material.

### EXAMPLES

Reference will now be made to more specific embodiments of the present disclosure and experimental results that provide support for such embodiments. The examples below more fully illustrate the disclosed and claimed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All of the experiments described in the examples were conducted in a PVD sputtering chamber with base pressure of 1E-7 mTorr. The camber is equipped with two or more targets to allow deposition of multiple layers without breaking vacuum. A mixture of gases (O, Ar, etc.) can be introduced to the chamber during process. The pedestal temperature can be tuned between room temperature up to 600° C. Finally, voltage can be applied to the different targets in a continuous way (DC), pulsed (PDC) or with RF frequency.

### Specific Examples

Example 1: As shown in Table 1, different refractive index values are obtained for different stacks deposited with and without an SnO₂ templating layer and also at different temperatures. Notably, when deposited without SnO₂ templating layer, no crystalline peaks are detected using X-ray Diffraction (XRD) for TiO₂ due to the lack of crystallinity for deposition temperatures up to 350° C. In contrast, the introduction of a SnO₂ templating layer promotes crystalline growth of TiO₂ starting at deposition temperatures around 150° C., with increasing refractive index of up to 2.81@460 nm depositing at 350° C.

TABLE 1

| 1^{st} layer SnO₂ | | | 2^{nd} layer TiO₂ | | |
|---|---|---|---|---|---|
| Thickness | Dep. | | Dep. | | Refractive Index |
| (Å) | Temp (° C.) | XRD | Temp (° C.) | XRD | @460 nm |
| No SnO₂ | n/a | n/a | 25 | no peak | 2.62 |
| | | | 150 | no peak | 2.64 |
| | | | 350 | no peak | 2.65 |
| 30-100 | 25 | no peak | 25 | no peak | 2.65 |
| 30-100 | 250 | polycrystalline | 150 | polycrystalline | 2.75 |
| 30-100 | 350 | polycrystalline | 350 | polycrystalline | 2.81 |

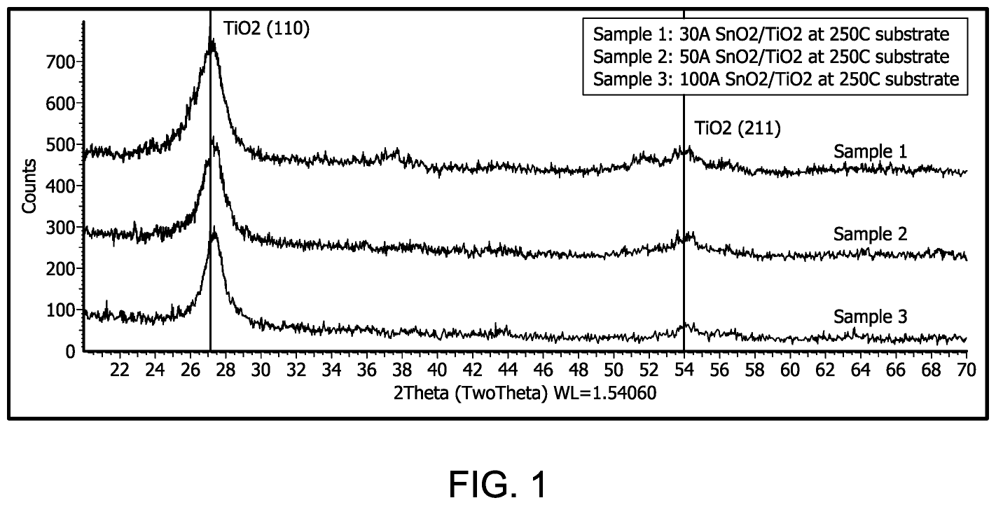

Example 2: As shown in Table 2, adjustments to the process parameters can be made to raise and/or tune the refractive index of the deposited TiO₂ (2^{nd} layer). This is demonstrated, for example, for the process parameters and results obtained when depositing TiO₂ at 350° C. with an SnO₂ (1^{st} layer) templating layer (deposited at 350° C.) having a thickness between 30 to 100 Å. Both the 1^{st} and 2^{nd} layer processes were conducted with a 12 sccm argon flow. The highest refractive index was obtained for SnO₂ thickness of 50 Å. FIG. 1 shows XRD scans corresponding to the same samples showing rutile TiO₂ growth in all cases.

TABLE 2

| | | | | | | 2^{nd} Layer Process Conditions | | | | | |
|---|---|---|---|---|---|---|---|---|---|---|---|
| | 1^{st} Layer Process Conditions | | | | | Target = TiO₂ | | | | | |
| | Target = SnO₂ | | | | | | | | | | n |
| | O₂ | | Pres, | Power | Thickness | O₂ | | Pres. | Power | Thickness | @460 |
| Ex. | (sccm) | O₂ % | (mTorr) | (W) | (Å) | sccm | O₂ % | (mTorr) | (W) | (Å) | nm |
| 1 | 48 | 80 | 5 | 150 | 30 | 48 | 80 | 3 | 500 | 361 | 2.815 |
| 2 | 48 | 80 | 5 | 150 | 50 | 48 | 80 | 3 | 500 | 371 | 2.818 |
| 3 | 48 | 80 | 5 | 150 | 100 | 48 | 80 | 3 | 500 | 385 | 2.802 |

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1.-137. (canceled)

1. A PVD process comprising the steps of:
(1) depositing a templating layer including one or more of a metal oxide selected from the group of SnO₂, GeO₂, TaO₂, TeO₂ on a substrate surface using a first target by the steps of:
(a) bringing the substrate to a temperature of about 100° C. to about 400° C.;
(b) introducing a mixture of oxygen (O) and one or more inert gas;
(c) performing pulsed DC reactive sputtering by applying voltage to the first target to generate a plasma,
wherein the templating layer has a thickness of between about 10 Å and about 125 Å; and
(2) depositing a high refractive index layer of rutile TiO₂ on the templating layer using a second target by the steps of:
(a) bringing the substrate to a temperature of about 100° C. to about 400° C.;
(b) introducing a mixture of oxygen (O) and one or more inert gas;
(c) performing pulsed DC reactive sputtering by applying voltage to the second target to generate a plasma.

2. The PVD process of claim 1, wherein the templating layer comprises a metal oxide selected from the group of SnO₂, GeO₂, TaO₂, TeO₂ and combinations thereof.

3. The PVD process of claim 1, wherein the templating layer comprises SnO₂.

4. The PVD process of claim 1, wherein the first target comprises one or more of a metal oxide material and a metal.

5. The PVD process of claim 1, wherein the first target comprises a metal selected from the group of Sn, Ge, Ta and Te.

6. The PVD process of claim 1, wherein the first target comprises a metal comprising Sn.

7. The PVD process of claim 1, wherein the second target comprises one or more of a metal oxide material and a metal.

8. The PVD process of claim 1, wherein the second target comprises a metal comprising Ti.

9. The PVD process of claim 1, wherein one or both of step 1(a) and step 2(a) the substrate is brought to a temperature of about 125° C. to about 375° C.

10. The PVD process of claim 1, wherein step 1(a) and step 2(a) are performed at the same temperature.

11. The PVD process of claim 1, wherein step 1(a) and step 2(a) are performed at substantially the same temperature.

12. The PVD process of claim 1, wherein step 1(a) and step 2(a) are performed at different temperatures.

13. The PVD process of claim 1, wherein one or both of step 1(b) and step 2(b) is carried out at a pressure between about 1 mTorr and about 10 mTorr.

14. The PVD process of claim 1, wherein step 1(b) and step 2(b) are performed at the same pressure.

15. The PVD process of claim 1, wherein step 1(b) and step 2(b) are performed at substantially the same pressure.

16. The PVD process of claim 1, wherein step 1(b) and step 2(b) are performed at different pressures.

17. The PVD process of claim 1, wherein the templating layer has a thickness of between about 15 Å and about 115 Å.

18. The PVD process of claim 1, wherein the high refractive index layer of rutile TiO₂ has a refractive index at 460 nm of about 2.70 to about 3.0.

19. The PVD process of claim 1, wherein the substrate comprises one or more of a transition metal oxide, a rare earth oxide-based material, a ternary oxide-based material, and a nitride-based material.

20. The PVD process of claim 1, wherein the substrate comprises one or more of a solid metal substrate and a metal silicide.

21. The PVD process of claim 1, wherein the substrate comprises a metal substrate comprising one or more of Au, Pd, Rh, Ru, W, Al, Ni, Ti, Co and Pt.

22. The PVD process of claim 1, wherein the substrate comprises a metal silicide comprising one or more of TiSi₂, CoSi₂ and NiSi₂.

23. The PVD process of claim 1, wherein the substrate comprises glass.

24. The PVD process of claim 1, wherein the substrate comprises a silicon oxide-based material.

25. The PVD process of claim 1, wherein the substrate comprises one or more of a semiconductor material and an insulator.

26. The PVD process of claim 1, wherein the substrate comprises a semiconductor material comprising one or more of Si, SiGe, GaAs, InP, diamond, GaN and SiC.

27. The PVD process of claim 1, wherein the substrate comprises an insulator comprising one or more of SiO₂, Si₃N₄, SiON, HfO₂, Ta₂O₅, ZrO₂, TiO₂, Al₂O₃ and barium strontium titanate.

28. The PVD process of claim 1, wherein the substrate comprises one or more of a plastic and a flexible substrate.

29. The PVD process of claim 1, wherein the substrate comprises one or more flexible substrate comprising a polymer.
